(19) United States
(12) Patent Application Publication
(10) Pub. No.: US 2007/0196719 A1
(43) Pub. Date: Aug. 23, 2007

(54) DEVICE FOR ASSEMBLING A BANDED FUEL CELL STACK

(76) Inventors: Graham E. Hill, Vancouver (CA); Rae Hartwell, Surrey (CA); Paul F. Meharg, Vancouver (CA); Frank Boonstra, Winterbourne (CA)

Correspondence Address: SEED INTELLECTUAL PROPERTY LAW GROUP PLLC, 701 FIFTH AVE, SUITE 5400, SEATTLE, WA, 98104, US

(21) Appl. No.: 11/679,056

(22) Filed: Feb. 26, 2007

Related U.S. Application Data
(63) Continuation of application No. 10/886,935, filed on Jul. 8, 2004, now abandoned.

(51) Int. Cl. H01M 8/24; H05K 13/04

(52) U.S. Cl. 429/37; 29/729

(57) ABSTRACT

A device for assembling a banded fuel cell stack with at least one custom-fit band comprises a frame, a base to support the stack while assembling, a press plate that is movable toward and away from the base to compress the stack under a constant force, band folding means to fold the band around the compressed stack such that the ends of the band overlap and welding means for welding the overlapped ends of the band. A method for assembling the banded fuel cell stack with at least one custom-fit band is also described. The device can be used to fit a plurality of compression bands around the assembled stack.

### CROSS-REFERENCE TO RELATED APPLICATION

This application is a continuation of U.S. patent application Ser. No. 10/886,935, filed Jul. 8, 2004, now pending, which application is incorporated herein by reference in its entirety.

### BACKGROUND OF THE INVENTION

1. Field of the Invention

The present invention generally relates to a device for assembling a banded fuel cell stack and, more specifically, to a device for compressing the stack under a constant force, folding at least one band around the compressed fuel cell stack and welding its overlapped ends to maintain the stack under a predetermined compression force.

2. Description of the Prior Art

Electrochemical fuel cells convert reactants, namely fuel and oxidant, into electric power through the electrochemical reactions that take place within the fuel cell. One type of fuel cell that has been used for automotive and other industrial applications because of its low operation temperature (around 80° C.) is the solid polymer fuel cell. Solid polymer fuel cells employ a membrane electrode assembly (“MEA”) that includes an ion exchange membrane disposed between two electrodes that carry a certain amount of electrocatalyst at their interface with the membrane. The electrocatalyst induces the electrochemical reactions that take place within the fuel cell to generate electricity. The membrane is ion conductive and separates the reactant streams (fuel and oxidant) from each other.

In typical fuel cells, the MEA is disposed between two electrically conductive separator plates. The separator plates are provided with channels that direct the flow of fuel and oxidant to the electrode layers. The plates are also current collectors and provide support to the MEA. The voltage produced by one fuel cell is not large enough to be used in many industrial applications. Therefore, two or more fuel cells are connected together, generally in series to increase the overall power output of the assembly. A coolant is circulated through the stack, generally through the channels provided in the separator plates, to absorb the heat generated by the exothermic fuel cell reactions. In order to properly separate the flow of fuel, oxidant and coolant, the stack typically employs seals placed between stack components.

The entire assembly of fuel cells connected in series forms the stack and is held together through various arrangements (rods, compression bands, etc.). A certain compression force needs to be applied to the assembled stack to ensure an adequate seal and to prevent any fuel, oxidant or coolant leaks and the inter-mixing of various fluid streams. Compression of the stack is also desirable in order to ensure sufficient electrical contact between the plates and the MEA, and to provide the electrical connection between the fuel cells making up the stack. The use of tie rods for compressing the stack suffers the disadvantage that it can significantly increase the stack volume and, depending on the location of the rods, can induce deflection of the plates over time.

A simpler, more compact and lightweight compression mechanism for a fuel cell stack is one that employs at least one compression band circumscribing the stack as described in U.S. Pat. No. 5,993,987. Generally, before the compression bands are installed or folded around a stack, it is recommended to compress the stack. Various techniques for compressing the stack are known for the purpose of assembling the stack or for stack testing. Most of these prior techniques assemble the stacks to a fixed height (as described, for example, in U.S. 20030203269). This results in variable seal and contact forces within the stack affecting the operation of the fuel cell. In some other methods, the stack is compressed under a constant compressive force (as described for example in WO 02/09216, U.S. 20030203269 or EP 0082516). A constant compressive force is advantageous because it gives the stack the desired load for seals and electrical contacts without damaging the components of the stack.

While significant advances have been made relating to assembly of fuel cells, there remains a need for improved devices for assembling fuel cells, particularly a banded fuel cell stack. Such improved devices preferably permit automatic assembly of a banded fuel cell stack by using a constant compression force and allow the mass-production of fuel cells.

### BRIEF SUMMARY OF THE INVENTION

A device is disclosed for assembling a banded fuel cell stack with one or more custom-fit bands, which comprises a frame, a base mounted on the frame for supporting the stack during assembly, a press plate that is movable toward and away from the base to compress the stack under constant force, a band folding means to fold the band around the compressed stack such that the band ends overlap and a welding means to weld the overlapped ends of the band.

The device may further comprise a stack support plate, band guides, stack guides to guide the stack during installation on the device and lateral stack locating means to position and guide the stack laterally during operation. The stack guides comprise runners of a greater height than the band guides for supporting the stack when it is manually pushed to its support plate on the device.

In one embodiment, the band folding means comprises first folding means that fold the band in a first direction around the stack and second folding means that fold the band in a second direction perpendicular to the first direction so that there is enough overlap of the ends of the band at the top of the stack to ensure a proper weld.

In another embodiment, the device further comprises a laser-welding device that welds the overlapped ends of the band. Other welding devices and methods may be used, such as resistive welding or mechanical deformation of the bands.

In still a further embodiment, a method is disclosed of assembling a banded fuel cell stack with at least one custom-fit band by using the above device, comprising the following steps:

compressing the stack under a predetermined compression force by lowering the press,

positioning at least one band within the band guides on the base,

folding at least one band around the compressed stack, and

welding the overlapped ends of each band using the welding means of the device.

The method may further comprise first sliding the pre-compressed stack on the stack guides to position it on the stack support plate of the device and locating the stack in operating position. The band is folded around the compressed stack by lowering the stack support plate to give an initial fold to the band, activating the first folding means to fold the band in a first direction around the stack, and activating the second folding means to fold both ends of the band in a second direction around the stack, perpendicular to the first direction so that the ends of the band overlap.

Generally, at least two bands are necessary for maintaining the stack in a compressed state, and the number of the bands depends on the stack's aspect ratio. The above device allows the folding of up to eight bands around the stack, in which case the above method applies to all of the bands installed on the device.

These and other aspects of the invention will be evident upon reference to the following detailed description and attached drawings.

### BRIEF DESCRIPTION OF THE DRAWINGS

FIG. 1 is a perspective view of the stack in a partially disassembled state.

FIG. 2 is a perspective view of the stack with several custom-fitted bands installed on the stack.

FIG. 3 is a view of the assembled Belleville spring pack.

FIG. 4 is a front view of the device for assembling a banded fuel cell stack.

FIG. 5 is a perspective view of the compression and strapping assembly of the device.

FIG. 6 is a perspective view of the base of the compression and strapping assembly.

FIGS. 7a to 7g show the steps of folding a band around the stack as performed during operation of the device.

FIG. 8 is a perspective view of the press plate of the compression and strapping assembly.

### DETAILED DESCRIPTION OF THE INVENTION

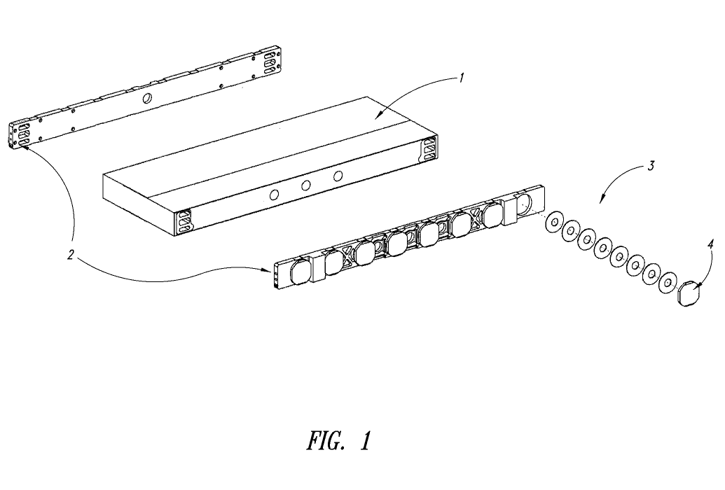

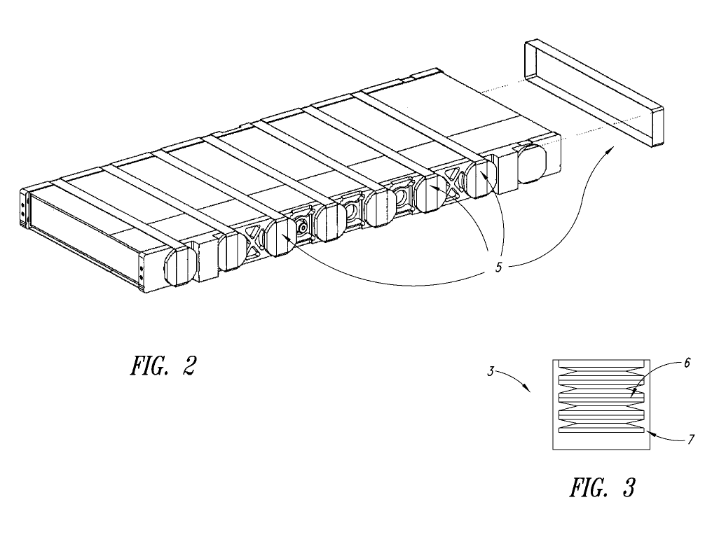

The present invention is generally directed to a device for automatically assembling a fuel cell stack used for automotive or other industrial purposes by folding multiple bands around the stack and welding their overlapped ends. As shown in FIGS. 1 and 2, fuel cell stack 1 is assembled between two end plates 2, one of them being provided with spring packs 3 and caps 4 that, together with the compression bands 5, ensure that the stack is maintained in a compressed state. Each of spring packs 3, as further shown in FIG. 3, comprises several Belleville disc springs 6 that are stacked one over the other and wrapped in Mylar® tape 7 to form the assembled pack. A spacer (not shown) may be placed between the springs, and the number of disc springs in the pack may vary.

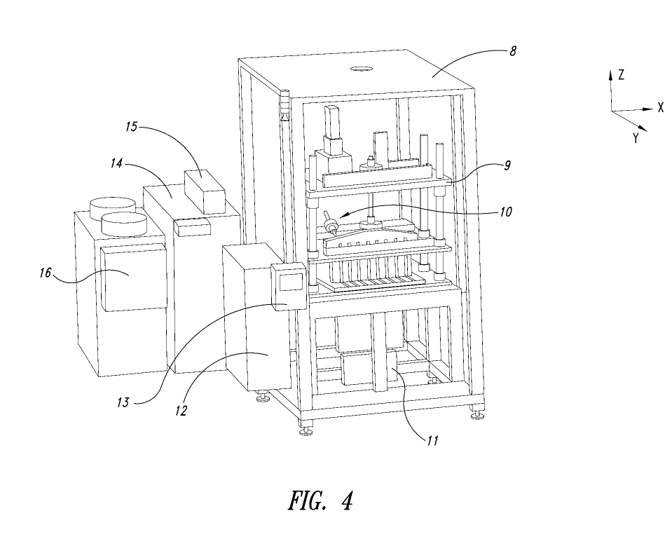

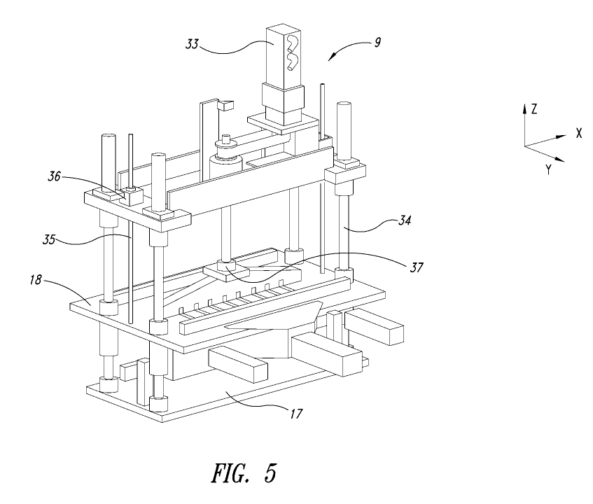

A representative device for assembling the banded fuel cell stack is shown in FIG. 4 and comprises a main frame 8 which supports the compression and strapping assembly 9 and the laser head 10, all the elements being located in an enclosure (not shown). Connected to the main frame of the device are an air compressor 11, a main electrical enclosure 12, an operator control panel 13, and a laser electrical enclosure 14 including a laser supply unit 15 and a chiller 16. The chiller serves to cool the laser apparatus. The compression and strapping assembly 9, as shown in FIG. 5, comprises a base 17 and a press plate 18.

The XYZ coordinates shown in FIGS. 4 to 6 correspond to the main axes of the device, X and Y axes being parallel to the longitudinal and the transversal axis, respectively, of the device in the horizontal plane, with the Z axis being the vertical axis of the device.

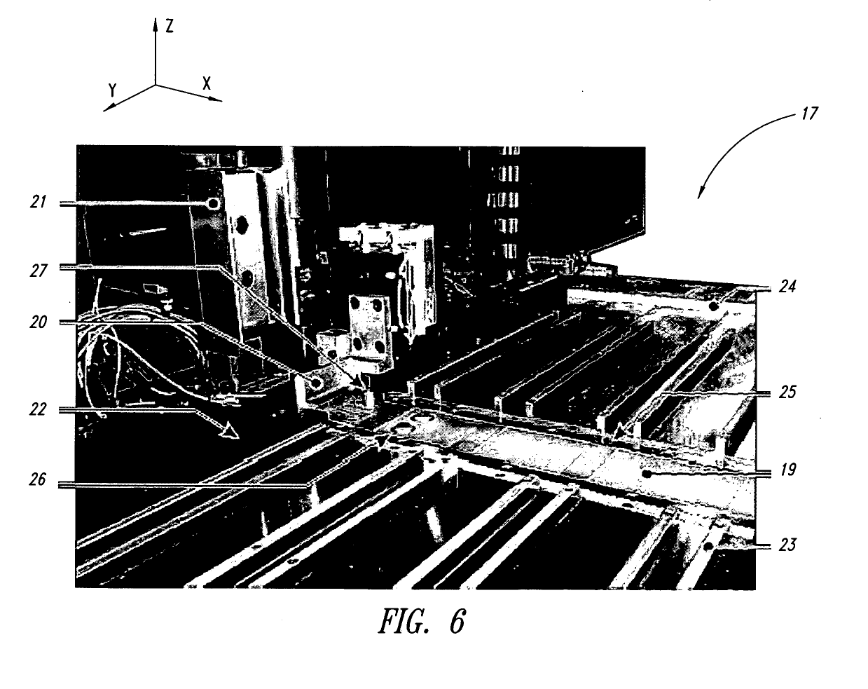

Referring to FIG. 6, the base 17 is provided with a stack support plate 19 that holds the stack during device operation, two stack guides 20 that support the stack while it is being installed on the device, two lateral stack locating means 21 for guiding the stack in the Z direction and locking the stack in position on the base in the X and Y directions, runners 22 for guiding the stack during its installation on the device, band guides 23 that hold the bands to be welded around the stack, a band end stop 24 for limiting the movement of the bands in the Y direction, and first folding means 25 that fold the band along each side of the stack. The stack is pushed along the runners 22 and is placed over the stack support plate 19 on the spring-loaded notches 26 provided on the plate 19 that allow a gap between the stack and the plate that facilitates the insertion of the bands under the stack. The runners 22 have a greater height than the band guides 23 to allow an easy insertion of the bands under the stack even during the stack installation on the base. The stack is oriented on the plate 19 so that the stack locating pin 27 fits in the fuel port of the stack. After the stack is placed on the plate 19, the lateral stack locating means 21 are pushed towards the stack to lock it in position. The band guides and the band end stop ensure the correct orientation and alignment of the band on the base so that the overlap of the band ends occurs at the top of the stack where they can be welded.

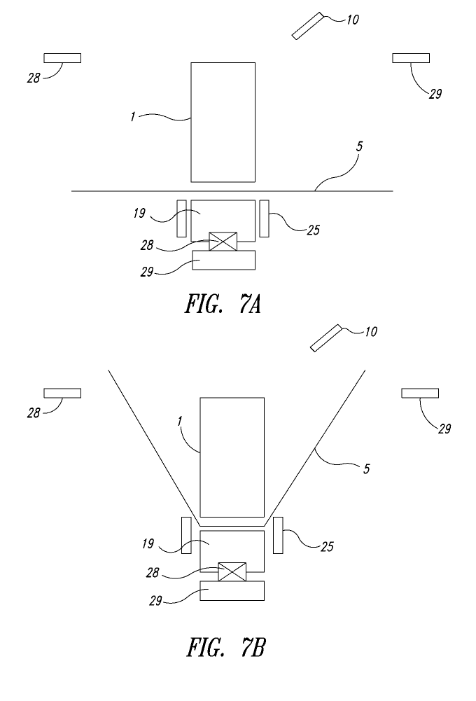

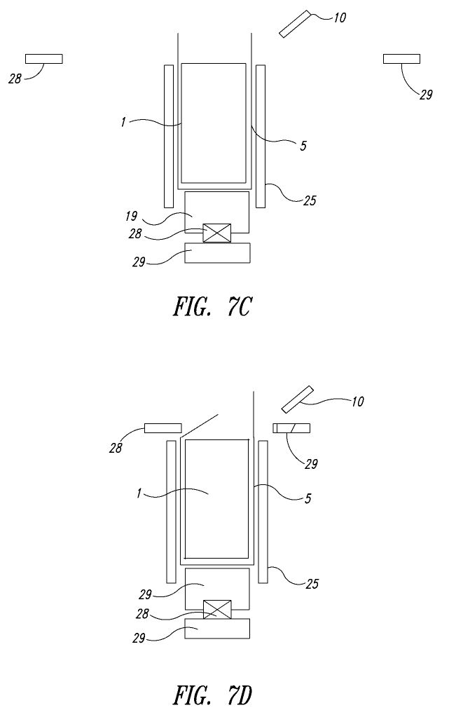

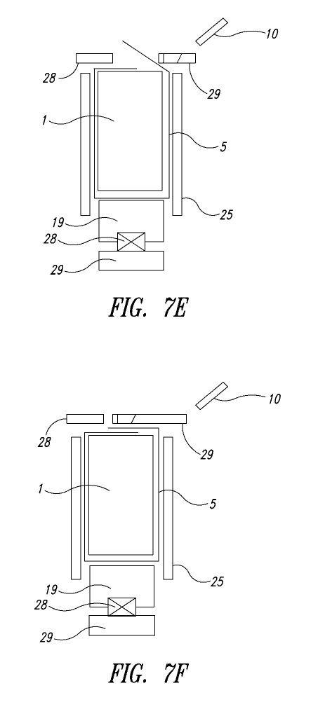

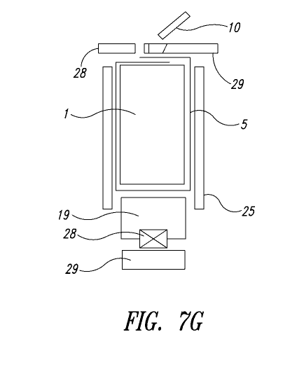

FIGS. 7a to 7g show the steps performed by the device to fold a band around the stack and weld it in position. In this regard, it should be noted that the gaps between the stack and the band and between the band and the folding means as shown in FIGS. 7a to 7g are exaggerated for demonstration purposes.

The band is first positioned under the stack as shown in FIG. 7a. As load is brought to the stack, the stack support plate 19 shown in FIG. 6 slightly drops because it is supported by die springs 28 on the bottom plate 29 to pre-fold the band towards its vertical position as shown in FIG. 7b. Then the first folding tools 25 shown in FIG. 6 are pushed up to bring the band in a vertical position in close proximity to the stack as shown in FIG. 7c. Next, the front form slide 30 is advanced towards the center to fold one side of the band at the top of the stack (as shown in FIG. 7d and 7e) and then the rear form slide 31 is also advanced towards the center to fold the other end of the band at the top of the stack to overlap with the first end of the band (as shown in FIG. 7e and 7f). The rear form slide is provided with a hole that allows the laser beam line of sight for welding of the overlapped ends of the band as shown in FIG. 7g.

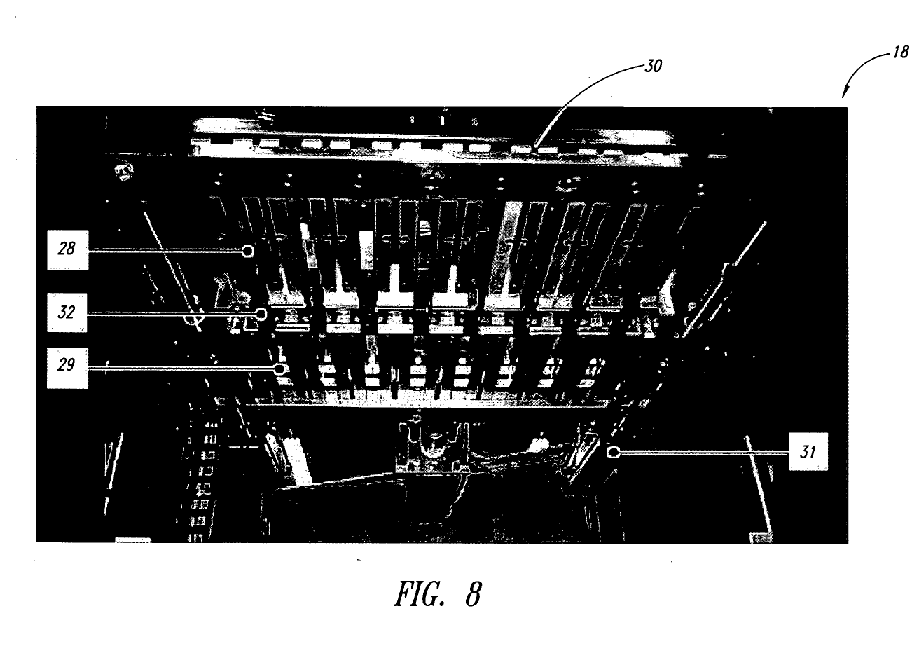

The front and rear form slides 30 and 31 will now be described in the context of the press plate 18 where they are located. The press plate 18, shown in FIG. 8, is provided with form slide guides 32 through which the second folding means comprising the front form slides 30 and the rear form slides 31 are advanced to fold the bands around the stack and hold them in place until the welding operation is completed. The pneumatic cylinders 33 move the front and rear form slides towards each other. The press plate 18 is also provided with vacuum nests 34 for locating the spring caps 4. The vacuum nests ensure the correct orientation of the caps when they are placed over the spring packs at the top of the endplate 2.

The compression and strapping assembly, as shown in FIG. 5, further comprises a servomotor 35 that lowers or raises the press plate 18 through a belt mechanism. The press plate is guided on four vertical posts 36 during its movement in the Z direction. The safety clamping rods 37 serve to prevent the sudden drop of the press plate by physically engaging the rod clamps 38. The drop may be caused by an electrical power outage or by problems with the pneumatic sources. A load cell 39 monitors the amount of force exerted by the servo driven press plate on the stack to maintain it at a constant value (e.g., 20000 N).

The laser head 10, shown in FIG. 4, is mounted to a servo driven linear actuator and is able to move in the X direction from one welding station to the next when more than one band is folded around the stack. Each welding station corresponds to the location of a band along the length of the stack.

The device is provided with sensors to ensure its proper operation. During the preparation for the strapping operation sensors are provided to make sure that the spring caps, the straps and the lateral stack locating means 21 are in place. During device operation other sensors signal to the operator if the cell row is in proper position, if the press plate 18 was brought to its full compression position and if the first folding means 25 and the front and rear form slides 30 and 31 are in position. If any of these conditions are not met the cycle stops, an error message is written to the operator interface and a red light flashes next to the operator on the control panel 13.

Next, the operation of the device in connection with FIGS. 4-8 will be described. The fuel cell stack is preliminarily compressed on a separate pre-compression stand at an interim force that allows the stack components to be pre-assembled in a unit block by manually installing several temporary bands on the stack with their ends held together with screws to maintain its approximate compression state. The temporary bands are placed between the places where the welded bands will be located. The fuel cell stack is then transferred to the base of the device with the end plate carrying the springs at the top. Then the operator manually pushes the stack on the runners 22 up to the two stack guides 20.

The stack guides 20 are lowered under the weight of the stack until the bottom end plate of the stack reaches the spring-loaded notches 26 that allow a gap between the stack and the stack support plate 19 for inserting one or more bands in the band guides 23. During this time the operator manually guides the stack so that the stack locating pin 27 is placed in the coolant port of the stack, a position that corresponds to the correct placement of the stack on the stack support plate 19 of the device. At this time the operator manually advances the two lateral stack locating means 21 towards the stack to reach a position in which they are placed next to the stack to guide it in the Z direction and block its movement in the X and Y direction. When the device starts operating, the lateral stack locating means are firmly pressed against the stack by pneumatic means. The band to be welded around the stack is then inserted in the band guide 23 and pushed towards the back of the base until it reaches the band end stop 24. This ensures that the band is positioned correctly on the base so that, when folded, its ends overlap at the top of the stack in a position that allows a proper weld. Generally, more than one band is needed for maintaining the stack in its compressed state. The bands are each inserted in the band guides, they are folded simultaneously and then each band welded separately. The device illustrated here can accommodate up to 8 bands.

Next, the vacuum source is turned on and the spring caps are placed in the vacuum nests 32 located in the press plate 18. At the same time, the lateral stack locating means 21 are pressed against the stack. At this stage, the stack and the bands are properly placed within the compression and strapping assembly and the device is ready to start the assembling process.

The device can operate in a manual or automatic mode. During the manual mode the operator can switch from one step to the next by using the keys on the operator control panel. Either way, the steps of the assembling process are as follows. First, the press plate 18 is lowered; it will reach the stack and it will increasingly compress the stack until the compression force sensed by the load cell 37 reaches the desired load. During this movement the caps become positioned over the springs placed at the top of the stack. Next, the stack support plate 19 carrying the stack in its compressed position is lowered so that the bands are slightly bent around the bottom of the stack, to bring them closer to the stack in preparation for the next step. The first folding means 25 are then raised to position the bands in close proximity to the stack. Next, the front form slides 30 on the press plate 18 are activated by the pneumatic cylinders 33 to fold the front portions of the bands over the top of the stack. This is followed by the activation of the rear form slides 31 by the pneumatic cylinders 33 to fold the back portions of the bands over the top of the stack so that they overlap with the front portions of the bands that have already been folded around the stack. Next, the automatic laser welding of the overlapped ends of the bands begins. The laser beam reaches the overlapped ends of each band through a hole in the rear form slide as shown in FIG. 7g. If more than one band is folded around the stack the laser head 10 is moved by the servo driven linear actuator from the first welding position corresponding to the first band folded around the stack to the next position, which corresponds to the next band placed on the base, until all the bands are welded.

After the welding process is finished, the front and rear form slides 30 and 31 are retracted, the first folding means 25 are lowered, the stack support plate 19 is lifted to its original inactive position, the press plate 18 is raised to its uppermost position and the lateral stack locating means 21 are retracted to allow the removal of the assembled stack.

The device for assembling a banded fuel cell stack and the operating method described above have the advantage that the custom-fit bands are installed under a constant force without overcompressing, which gives the seals and electrical contacts in the stack the desired load without damaging the components. The other advantage is that this automated equipment is suitable for mass-producing fuel cell stacks provided with custom-fit bands. While particular steps, elements, embodiments and applications of the present invention have been shown and described, it will be understood, of course, that the invention is not limited thereto since modifications may be made by persons skilled in the art, particularly in light of the foregoing teachings. It is therefore contemplated by the appended claims to cover such modifications as incorporate those steps or elements which come within the spirit and scope of the invention.

What is claimed is:

1. A device for assembling a banded fuel cell stack with a custom-fit welded band comprising:
a frame;
a base mounted on the frame for supporting the stack while assembling;
a press plate that is movable toward and away from the base to compress the stack under a constant force;
band folding means to fold the band ends around the compressed stack while being compressed such that the band ends overlap; and
welding means to weld the overlapped ends of the band.

2. The device of claim 1 wherein the base further comprises:
a stack support plate;
at least one band guide to position at least one band on the base;
stack guides to guide the stack during installation on the device; and
lateral stack locating means for positioning and guiding the stack during operation.

3. The device of claim 2 wherein the stack guides comprise runners of a greater height than the band guide for supporting the stack.

4. The device of claim 1 wherein the band folding means comprises first folding means to fold the bands in a first direction around the stack.

5. The device of claim 1 wherein the band folding means comprises second folding means to fold the bands in a second direction perpendicular to the first direction.

6. The device of claim 1 wherein the welding means is a laser-welding device.

7. The device of claim 1 whereby at least two stacks are assembled and the height of one stack is different than the height of the other stack.

8. A method of assembling a banded fuel cell stack with a custom-fit welded band comprising the steps of:
providing the device of claim 1;
compressing the stack under a predetermined compression force by lowering the press;
positioning at least one band within the band guides on the base;
folding at least one band around the compressed stack; and
welding the overlapped ends of each band using the welding means of the device.

9. The method of claim 1 further comprising the step of first sliding a pre-compressed stack on the stack guides to position it on the stack support plate of the device and locating the stack in the operating position.

10. The method of claim 1 wherein folding the band around the compressed stack comprises lowering the stack support plate to give an initial fold to the band, activating the first folding tools to fold the band in a first direction around the stack and activating the second folding tools to fold both ends of the band in a second direction around the stack, perpendicular to the first direction, so that the ends of the band overlap.

11. The method of claim 1 whereby at least two stacks are assembled and the height of one stack is different than the height of the other stack.
